(19) United States
(12) Patent Application Publication
(10) Pub. No.: US 2017/0226654 A1
(43) Pub. Date: Aug. 10, 2017

(54) MAGNESIUM ALLOY SUBSTRATE

(71) Applicant: HEWLETT-PACKARD DEVELOPMENT COMPANY, L.P., HOUSTON, TX (US)

(72) Inventors: CHALAM KASHYAP, FORT COLLINS, CO (US); KUAN-TING WU, TAIPEI CITY (TW)

(21) Appl. No.: 15/501,230

(22) PCT Filed: Oct. 27, 2014
(86) PCT No.: PCT/US2014/062369

§ 371 Date: Feb. 2, 2017

(51) Int. Cl. C25D 13/14; C25D 5/48; C25D 11/30; C23C 28/00; C25D 13/22; C23C 14/58; C23C 16/56; C25D 7/04; C25D 13/20

(52) U.S. Cl. CPC C25D 13/14; C25D 7/04; C25D 5/48; C25D 11/30; C25D 13/20; C25D 13/22; C23C 14/5853; C23C 16/56; C23C 28/00

(57) ABSTRACT

According to one example, preparing a substrate for an electronic device can include forming a deposition layer on a magnesium alloy substrate, anodizing the magnesium alloy substrate, and forming an electrophoretic deposition layer on the anodized magnesium alloy substrate.

Examples of electronic devices include laptop computers, tablets, media players, and cellular telephones, among others. Electronic devices are becoming increasingly more sophisticated, powerful and user friendly. Various electronic devices can have differing characteristics.

### BRIEF DESCRIPTION OF THE FIGURES

FIG. 1 illustrates a block diagram of an example of a method according to the present disclosure.

FIG. 2 illustrates a block diagram of examples of a processing resource, a memory resource, and a computer-readable medium according to the present disclosure.

FIG. 3 illustrates a portion of a substrate for an electronic device in accordance with one or more examples of the present disclosure.

### DETAILED DESCRIPTION

Examples of the present disclosure provide substrates for an electronic device and methods for preparing the substrates. Examples of electronic devices include laptop computers, tablets, media players, and cellular telephones, among others. A substrate, which may be referred to as a housing among other terms, may be utilized to support and/or house a number of components of the electronic device.

As mentioned, examples of the present disclosure provide substrates for an electronic device and methods for preparing the substrate. The methods for preparing the substrate disclosed herein can help to provide substrates having desirable characteristics. For instance, the substrates disclosed herein may have a desirable luster, which may be indicated by a particular gloss value (G) and/or particular “Lab” values, where “L” represents lightness and “a” and “b” represent color-opponent dimensions. Further, the substrates disclosed herein may have a desirable tactile characteristic and/or mechanical property, such as hardness, among other benefits.

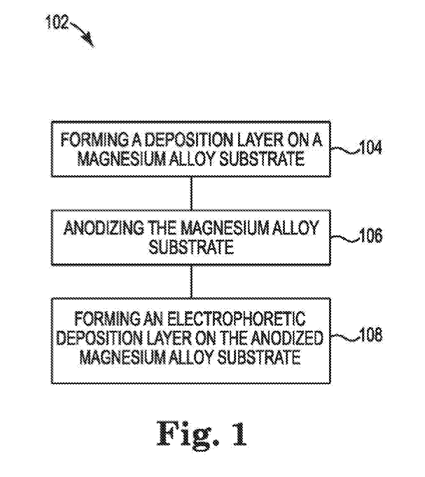

FIG. 1 illustrates a block diagram of an example of a method 102 according to the present disclosure. The method 102 may be utilized for preparing a substrate for an electronic device.

At 104, the method 102 can include forming a deposition layer on a magnesium alloy substrate. As mentioned, a substrate may be utilized to support and/or house a number of components of an electronic device. Some examples of the present disclosure provide that the substrate can be a magnesium alloy substrate. The magnesium alloy substrate can include magnesium, titanium, zinc, and an element selected from the group consisting of aluminum and lithium. Commercially available examples of magnesium alloys include AZ91, which includes magnesium, aluminum, and zinc, and LZ91, which includes magnesium, lithium, and zinc, among others.

Some examples of the present disclosure provide that a magnesium alloy may be cast to form a cast magnesium alloy substrate. For instance, the magnesium alloy may be sand cast or die cast to form the cast magnesium alloy substrate. For some applications, it may be preferable to die cast the magnesium alloy to form the cast magnesium alloy substrate.

Some examples of the present disclosure provide magnesium alloy substrate may be machined. For instance, the magnesium alloy substrate may be machined to accommodate various elements of an electronic device. An example of machining is computer numerical control machining. However, examples of the present disclosure are not so limited.

Some examples of the present disclosure provide that a magnesium alloy substrate can be surface treated. For instance, a magnesium alloy substrate, such as a cast magnesium alloy substrate that has been machined, may be surface treated prior to further preparation of the substrate. Examples of surface treatment include, but are not limited to cleaning and polishing. The surface treatment can be utilized to remove oxides, hydroxides, and/or excess lubricant from the magnesium alloy substrate, for example.

As mentioned, the method 102 can include 104 forming a deposition layer on a magnesium alloy substrate. The deposition layer, which may also be referred to as a coating among other terms, may be formed by different processes for various applications. Some examples of the present disclosure provide that a layer, e.g., the deposition layer, is uniform on an exposed surface, such as the magnesium alloy substrate. However, as used herein, a “layer” may be un-uniform on the exposed surface. Additionally, a “layer” may not occur on all portions of the exposed surface. Such a partial layer is understood to be a layer herein. Some examples of the present disclosure provide that forming the deposition layer is anodization preparation. For instance, anodization of the magnesium alloy substrate can be performed subsequent to formation of the deposition layer.

The deposition layer can include various metals. The metals include aluminum, magnesium, lithium, zinc, chromium, nickel, titanium, niobium, stainless steel, copper, and alloys thereof, for example. Examples of the present disclosure provide that the deposition layer can have a thickness from about 0.2 microns to about 150 microns. Some examples of the present disclosure provide that the deposition layer can have a thickness from about 0.5 microns to about 100 microns.

Some examples of the present disclosure provide that the deposition layer can be formed by electroplating. Electroplating is a process where a number of deposition layers of a metal can be formed on the magnesium alloy substrate by passing a positively charged electrical current through an electroplating bath containing metal ions and a negatively charged electrical current through the magnesium alloy substrate. The electroplating bath may be a solution, e.g., an aqueous solution.

The electroplating bath may include precursors that are utilized to form the deposition layer on the magnesium alloy substrate. For instance, the deposition layer can include precursors, such as soluble metal salts among others that dissociate to metal ions in the electroplating bath. Different concentrations of precursors may be utilized for various applications. The metal ions can be deposited on the magnesium alloy substrate to form the deposition layer.

As mentioned, forming the deposition layer on the magnesium alloy substrate can include applying a current through the electroplating bath. Same examples of the present disclosure provide that a voltage from 10 volts to 400 volts is utilized. Some examples of the present disclosure provide that a voltage from 25 volts to 100 volts is utilized. Forming the deposition layer can occur at temperature of 0° C. to 80° C. Some examples of the present disclosure provide that forming the deposition layer can occur at temperature of 10° C. to 30° C.

Some examples of the present disclosure provide that the deposition layer can be formed by physical vapor deposition. Examples of physical vapor deposition include ion-beam sputtering, reactive sputtering, ion-assisted deposition, high-target-utilization sputtering, high-power impulse magnetron sputtering, gas flow sputtering, and chemical vapor deposition, among others. Physical vapor deposition is a process where a number of deposition layers of a metal can be formed on the magnesium alloy substrate by contacting metal, as discussed herein, to be deposited with the magnesium alloy substrate. Different physical vapor deposition conditions may be utilized for various applications.

At 106, the method 102 can include anodizing the magnesium alloy substrate. Anodizing is an electrochemical conversion process that may be utilized to form an anodization layer, e.g., an oxide film. Different anodization processes may be utilized for various applications. Examples of the anodization process include, but are not limited to, Type I-chromic acid anodize, Type II-sulfuric acid anodize. Type III hard anodize; the anodization process can be Class 1, referring to non-dyed, or Class 2, referring to dyed, according to Military Specification MIL-A-8625. The anodization processes may be performed according to a standard, such as MIL-A-8625, AMS 2468C, BS 5599:1978, ISO 10074:1994, or AMA-2482, for example. Examples of the present disclosure provide that the anodization layer can have a thickness from about 0.5 microns to about 30 microns.

At 108, the method 102 can include forming an electrophoretic deposition layer on the anodized magnesium alloy substrate. Electrophoretic deposition is a process where particles, such as colloidal particles, suspended in a liquid medium migrate under the influence of an electric field and are deposited onto a surface, e.g., the anodized magnesium alloy substrate, to form the electrophoretic deposition layer. Electrophoretic deposition, in contrast to electroplating, is a non-Faradic process.

Forming the electrophoretic deposition layer on the anodized magnesium alloy substrate can include submerging the anodized magnesium alloy substrate in an electrophoretic deposition coating bath. The electrophoretic deposition coating bath may be a solution, e.g., an organic solution.

The electrophoretic deposition coating bath may include precursors that are utilized to form the electrophoretic deposition layer on the anodized magnesium alloy substrate. For instance, the electrophoretic deposition coating bath can include precursors, such as colloidal particles, among others. Different concentrations of precursors may be utilized for various applications. The colloidal particles can be deposited on the anodized magnesium alloy substrate to form the electrophoretic deposition layer. The electrophoretic deposition layer can include various components including, polyacrylic polymers, epoxy polymers, inorganic particles, and/or metals. Some examples of the present disclosure provide that powders, such as silver powder and/or pearl powder, among others, may be utilized to form the electrophoretic deposition layer. The electrophoretic deposition layer can include aluminum, magnesium, lithium, zinc, titanium, niobium, stainless steel, copper, and alloys thereof, for example.

Forming the electrophoretic deposition layer on the anodized magnesium alloy substrate can include applying a current through the electrophoretic deposition coating bath. Some examples of the present disclosure provide that a voltage from 10 volts to 250 volts is utilized. Some examples of the present disclosure provide that a voltage from 25 volts to 100 volts is utilized. Forming the electrophoretic deposition layer can occur at temperature of 25° C. to 40° C. Some examples of the present disclosure provide that forming the electrophoretic deposition layer can occur at temperature of 10° C. to 30° C. Examples of the present disclosure provide that the electrophoretic deposition layer can have a thickness from about 0.5 microns to about 100 microns. Some examples of the present disclosure provide that the electrophoretic deposition layer can have a thickness from about 3 microns to about 30 microns.

In various examples, the method can include forming a functional coating layer on the anodized magnesium alloy substrate. For instance, a functional coating layer can be formed on the anodized magnesium alloy substrate subsequent to the electrophoretic deposition layer being formed on the anodized magnesium alloy substrate. Examples of the functional coating layer include, but are not limited to, anti-finger print coatings, anti-bacterial coatings, anti-smudge coatings, protection coatings, insulation coatings, and soft touch coatings. The functional coating layer can be formed by various processes. The functional coating layer can have different thicknesses for various applications.

In various examples, the method can include cutting a portion of the magnesium alloy substrate. For instance, a portion of the magnesium alloy substrate may be cut subsequent to formation of the electrophoretic deposition layer and/or the functional coating layer. Some examples of the present disclosure provide that cutting the portion of the magnesium alloy substrate includes diamond cutting. Diamond cutting is a process that may be utilized to cut metal. Some examples of the present disclosure provide that diamond cutting the portion of the magnesium alloy substrate includes forming a chamfer. For instance, a portion of the magnesium alloy substrate may be diamond cut to form a beveled edge that connects two surfaces of the magnesium alloy substrate.

In various examples, the method can include forming a second electrophoretic deposition layer on the magnesium alloy substrate. The second electrophoretic deposition layer can be formed as the electrophoretic deposition layers previously discussed herein. The second electrophoretic deposition layer can be formed on various portions of the magnesium alloy substrate. For instance, the second electrophoretic deposition layer can be formed on a first electrophoretic deposition layer, a functional coating layer, and/or a diamond cut portion of the magnesium alloy substrate.

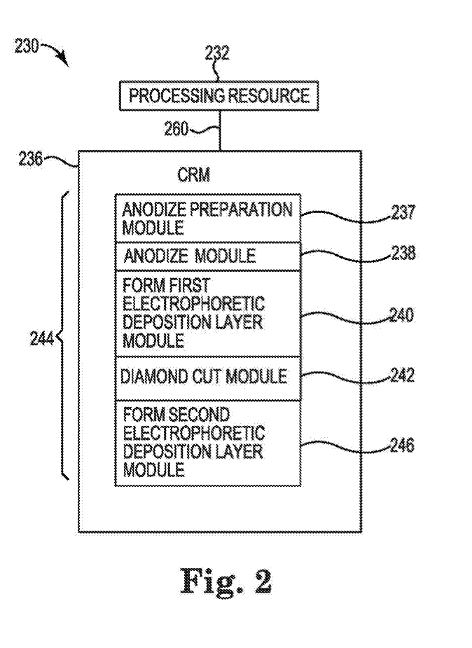

FIG. 2 illustrates a block diagram illustrating examples of a processing resource, a memory resource, and a computer-readable medium according to the present disclosure. The computing device 230 can utilize software, hardware, firmware, and/or logic to perform a number of functions. The hardware, for example can include a number of processing resources, e.g., processing resource 232, computer-readable medium (CRM) 236, etc. The program instructions, e.g., computer-readable instructions (CRI) 244, can include instructions stored on the CRM 236 and executable by the processing resource 232 to implement a desired function, such as perform an anodization preparation on a cast magnesium alloy substrate, anodize the cast magnesium alloy substrate, form a first electrophoretic deposition layer on the anodized cast magnesium alloy substrate, diamond cut a portion of the anodized cast magnesium alloy substrate, and form a second electrophoretic deposition layer on the diamond cut portion of the cast magnesium alloy substrate, among others.

CRM 236 can be in communication with a number of processing resources other than processing resource 232. The processing resource 232 can be in communication with a tangible non-transitory CRM 236 storing a set of CRI 244 executable by one or more of processing resource, as described herein. The CRI 244 can also be stored in remote memory managed by a server and represent an installation package that can be downloaded, installed, and executed.

Processing resource 232 can execute CRI 244 that can be stored on an internal or external non-transitory CRM 236. The processing resources 232 can execute CRI 244 to perform various functions, including the functions described herein, such as those discussed with FIG. 1, for instance.

The CRI 244 can include a number of modules, such as, for example, modules 237, 238, 240, 242, and 246. Modules 237, 238, 240, 242, and 246 in CRI 244 when executed by the processing resource 232 can perform a number of functions, as discussed herein.

Modules 237, 238, 240, 242, and 246 can be sub-modules of other modules. For example, the form first electrophoretic deposition layer module 240 and the form second electrophoretic deposition layer module 246 can be sub-modules and/or contained within a single module. Furthermore, modules 237, 238, 240, 242, and 246 can comprise individual modules separate and distinct from one another.

An anodize preparation module 237 can comprise CRI 244 and can be executed by the processing resource 232 to perform an anodization preparation on a cast magnesium ahoy substrate. Anodization preparation can include forming a deposition layer by electroplating or physical vapor deposition, as discussed herein.

An anodize module 238 can comprise CRI 244 and can be executed by the processing resource 232 to anodize cast magnesium alloy substrate. As discussed herein, anodization is an electrochemical conversion process that may be utilized to form an anodization layer, such as an oxide film.

A form first electrophoretic deposition layer module 240 can comprise CRI 244 and can be executed by the processing resource 232 to form an electrophoretic deposition layer, e.g., a first electrophoretic deposition layer, on the cast magnesium alloy substrate.

A diamond cut module 242 can comprise CRI 244 and can be executed by the processing resource 232 to diamond cut a portion of the anodized cast magnesium alloy substrate.

A form second electrophoretic deposition layer module 246 can comprise CRI 244 and can be executed by the processing resource 232 to form an electrophoretic deposition layer, e.g., a second electrophoretic deposition layer, on the cast magnesium alloy substrate.

In a number of examples, a form functional coating layer module (not pictured) can comprise CRI 244 and can be executed by the processing resource 232 to form a functional coating layer, as discussed herein, on the cast magnesium alloy substrate.

A non-transitory CRM 236, as used herein, can include volatile and/or non-volatile memory. Volatile memory can include memory that depends upon power to store information, such as various types of dynamic random access memory (DRAM), among others. Non-volatile memory can include memory that does not depend upon power to store information. Examples of non-volatile memory can include solid state media such as flash memory, electrically erasable programmable read-only memory (EEPROM), phase change random access memory (PCRAM), magnetic memory such as a hard disk, tape drives, floppy disk, and/or tape memory, optical discs, digital versatile discs (DVD), Blu-ray discs (BD), compact discs (CD), and/or a solid state drive (SSD), etc., as well as other types of computer-readable media.

The non-transitory CRM 236 can be integral, or communicatively coupled, to a computing device, in a wired and/or a wireless manner. For example, the non-transitory CRM 236 can be an internal memory, a portable memory, a portable disk, or a memory associated with another computing resource, e.g., enabling CRIB 244 to be transferred and/or executed across a network such as the Internet.

The CRM 236 can be in communication with the processing resource 232 via a communication path 260. The communication path 260 can be local or remote to a machine, e.g., a computer, associated with the processing resource 232. Examples of a local communication path 260 can include an electronic bus internal to a machine, e.g., a computer, where the CRM 236 is one of volatile, non-volatile, fixed, and/or removable storage medium in communication with the processing resource 232 via the electronic bus. Examples of such electronic buses can include Industry Standard Architecture (ISA), Peripheral Component Interconnect (PCI), Advanced Technology Attachment (ATA), Small Computer System Interface (SCSI), Universal Serial Bus (USB), among other types of electronic buses and variants thereof.

The communication path 260 can be such that the CRM 236 is remote from processing resources, e.g., processing resource 232, such as in a network connection between the CRM 236 and the processing resource, e.g., processing resource 232. That is, the communication path 260 can be a network connection. Examples of such a network connection can include a local area network (LAN), wide area network (WAN), personal area network (PAN), and the Internet, among others. In such examples, the CRM 236 can be associated with a first computing device and the processing resource 232 can be associated with a second computing device. For example, a processing resource 232 can be in communication with a CRM 236, wherein the CRM 236 includes a set of instructions and wherein the processing resource 232 is designed to carry out the set of instructions.

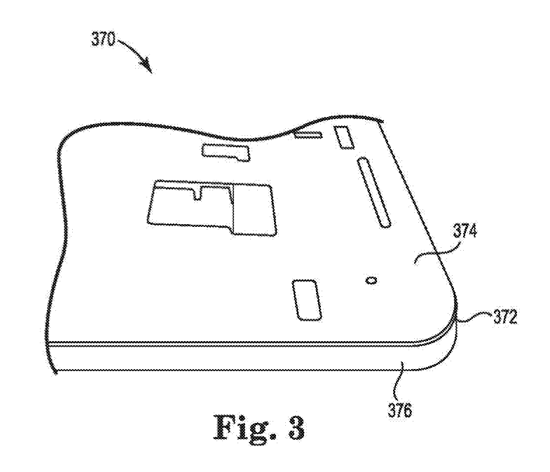

FIG. 3 illustrates a portion of a substrate 370 for an electronic device accordance with one or more examples of the present disclosure. As discussed herein, the substrate 370 can be a magnesium alloy substrate, e.g. a cast magnesium alloy substrate. The substrate 370 can include various elements, such as magnesium, zinc, aluminum, and/or lithium, for instance.

The substrate 370 can have a deposition layer formed thereon. The deposition layer can be formed as the deposition layers previously discussed herein. The deposition layer can be formed by different processes for various applications. For instance, the deposition layer can be formed by an electroplating process or a physical vapor deposition process.

Subsequent to formation of the deposition layer, the substrate 370 can be anodized, as discussed herein. Different anodization processes may be utilized for various applications.

Subsequent to anodization, an electrophoretic deposition layer can be formed on the substrate 370. The electrophoretic deposition layer can be formed as the electrophoretic deposition layers previously discussed herein.

Some examples of the present disclosure provide that subsequent to formation of the electrophoretic deposition layer, a functional coating layer can be formed on the substrate 370. Different functional coating layers may be utilized for various applications. The functional coating layer can be formed as the functional coating layers previously discussed herein.

Some examples of the present disclosure provide that the substrate 370 can include a chamfer 372. The chamfer 372 can connect a first surface 374 of the substrate 370 and a second surface 376 of the substrate 370. The chamfer 372 can be formed by diamond cutting, as discussed herein.

Some examples of the present disclosure provide that subsequent to forming the chamfer 372, a second electrophoretic deposition layer can be formed on the substrate 370. The second electrophoretic deposition layer can be formed on various portions of the substrate 370. For instance, the second electrophoretic deposition layer can be formed on another electrophoretic deposition layer, e.g., a first electrophoretic deposition layer, a functional coating layer, and/or the chamfer 372. The second electrophoretic deposition layer can be formed as the electrophoretic deposition layers previously discussed herein,

The substrates disclosed herein, e.g., a portion of substrate 370, may have a desirable luster as indicated by a particular gloss value. Examples of the present disclosure provide that the substrates disclosed herein, such as chamfer 372, can have a gloss value from 70 to 98 units as measured by ASTM D523 at a 60° viewing angle. Some examples of the, present disclosure provide that the substrates disclosed herein can have a gloss value from 85 to 95 units as measured by ASTM D523 at a 60° viewing angle.

As used herein, “logic” is an alternative or additional processing resource to perform a particular action and/or function, etc., described herein, which includes hardware, e.g., various forms of transistor logic, application specific integrated circuits (ASICs), etc., as opposed to computer executable instructions, e.g., software, firmware, etc., stored in memory and executable by a processor.

The specification examples are utilized to provide a description. Since many examples can be made without departing from the spirit and scope of the system and method of the present disclosure, this specification sets forth some of the many possible example configurations and implementations.

In the detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be used and the process, electrical, and/or structural changes may be made without departing from, the scope of the present disclosure.

The figures herein follow a numbering convention in which the first digit or digits correspond to the drawing figure number and the remaining digits identify an element or component in the drawing. Elements shown in the various examples herein can be added, exchanged, and/or eliminated so as to provide a number of additional, examples of the present disclosure,

In addition, the proportion and the relative scale of the elements provided in the figures are intended to illustrate the examples of the present disclosure, and should not be taken in a limiting sense. As used herein, “a number of” an entity, an element, and/or feature can refer to one or more of such entities, elements, and/or features.

What is claimed:

1. A method for preparing a substrate for an electronic device comprising:
forming a deposition layer on a magnesium alloy substrate;
anodizing the magnesium alloy substrate; and
forming an electrophoretic deposition layer on the anodized magnesium alloy substrate.

2. The method of claim 1, further comprising forming a functional coating layer on the anodized magnesium alloy substrate.

3. The method of claim 1, wherein forming the deposition layer on the anodized magnesium alloy substrate comprises electroplating.

4. The method of claim 1, wherein forming the deposition layer on the anodized magnesium alloy substrate comprises physical vapor deposition.

5. The method of claim 1, further comprising diamond cutting a portion of the magnesium alloy substrate.

6. The method of claim 5, wherein diamond cutting a portion of the magnesium alloy substrate includes forming a chamfer.

7. A non-transitory computer-readable medium storing a set of instructions for preparing a substrate for an electronic device executable by a processing resource to:
perform an anodization preparation on a cast magnesium alloy substrate, wherein the anodization preparation is selected from the group consisting of electroplating and physical vapor deposition;
anodize the cast magnesium alloy substrate;
form a first electrophoretic deposition layer on the anodized cast magnesium alloy substrate;
diamond cut a portion of the anodized cast magnesium alloy substrate; and
form a second electrophoretic deposition layer on the diamond cut portion of the cast magnesium alloy substrate.

8. The medium of claim 7, wherein the cast magnesium alloy substrate includes zinc and an element selected from the group consisting of aluminum and lithium.

9. The medium of claim 7, wherein the cast magnesium alloy substrate is die cast.

10. The medium of claim 7, further comprising instructions executable by a processing resource to form a functional coating layer on the cast magnesium alloy substrate.

11. The medium of claim 10, wherein the functional coating is selected from the group consisting of an anti-finger print coating, an anti-bacterial coating, an anti-smudge coating, a protection coating, an insulation coating, and a soft touch coating.

12. The medium of 7, wherein the physical vapor deposition is a process selected from the group consisting of ion-beam sputtering, reactive sputtering, ion-assisted deposition, high-target-utilization sputtering, high-power impulse magnetron sputtering, gas flow sputtering, and chemical vapor deposition.

13. A substrate for an electronic device comprising:
a cast magnesium alloy substrate including zinc and an element selected from the group consisting of aluminum and lithium,
wherein
a deposition layer is formed on the cast magnesium alloy substrate by a process selected from the group consisting of electroplating and physical vapor deposition;
the cast magnesium alloy substrate is anodized subsequent to formation of the deposition layer; and
an electrophoretic deposition layer is formed on the cast magnesium alloy substrate subsequent to anodization.

14. The substrate of claim 13, wherein a functional coating layer is formed on the cast magnesium alloy substrate subsequent to formation of the electrophoretic deposition layer.

15. The substrate of claim 14, wherein a chamfer is formed by diamond cutting a portion of the cast magnesium alloy substrate and a second electrophoretic deposition layer is formed on the chamfer.
